(19) United States
(12) Patent Application Publication
(10) Pub. No.: US 2006/0087034 A1
(43) Pub. Date: Apr. 27, 2006

(54) Bumping process and structure thereof

(75) Inventors: Min-Lung Huang, Kaohsiung City (TW); Yi-Hsin Chen, Kaohsiung City (TW); Jia-Bin Chen, Tainan City (TW)

Correspondence Address: THOMAS, KAYDEN, HORSTEMEYER & RISLEY, LLP, 100 GALLERIA PARKWAY, NW, STE 1750, ATLANTA, GA, 30339-5948, US

(73) Assignee: Advanced Semiconductor Engineering, Inc.

(21) Appl. No.: 11/236,196

(22) Filed: Sep. 27, 2005

(30) Foreign Application Priority Data
Oct. 22, 2004 (TW) 93132120

(51) Int. Cl. H01L 23/48; H01L 21/44

(52) U.S. Cl. 257/737; 438/613; 438/614; 438/615; 257/762; 257/779

(57) ABSTRACT

A bumping process includes the steps of: firstly, providing a wafer; forming a first photo-resist layer on a active surface of the wafer and forming at least a first opening on the first photo-resist layer; next, forming a first copper pillar in the first opening; next, forming a second photo-resist layer on the first photo-resist layer and forming at least a second opening on the second photo-resist layer, wherein the second opening smaller than the first opening so that a portion of the surface of the first copper pillar is exposed in the second opening; then, forming a second copper pillar in the second opening; finally, forming a solder layer on the second copper pillar; and removing the first and second photo-resist layers.

This application claims the benefit of Taiwan application Serial No. 93132120, filed Oct. 22, 2004, the subject matter of which is incorporated herein by reference.

### BACKGROUND OF THE INVENTION

1. Field of the Invention

The invention relates in general to a semiconductor manufacturing process, and more particularly to a bumping process of wafer.

2. Description of the Related Art

In the semiconductor industry, the manufacturing process of integrated circuits (IC) is divided into three main stages: the manufacturing of wafer, the manufacturing of IC, and the package of IC. The die is manufactured according to the steps of manufacturing the wafer, performing circuit design, performing several mask manufacturing processes, and dividing the wafer. Every die formed by dividing the wafer is electrically connected to a carrier via a bonding pad disposed on the die to form a chip package structure. The chip package structure is further categorized into three types, namely, the wire bonding type, the flip chip bonding type, and the tape automatic bonding type.

Referring to FIG. 1˜FIG. 5, flowcharts of a bumping process of a conventional wafer are shown. At first, referring to FIG. 1, an under bump metallurgy 110 is formed on the entire surface of a wafer 100 and is covered up by a photo-resist layer 120. Next, referring to FIG. 2, several openings 122 are formed on a photo-resist layer 120 using the imaging technology of exposure and development, and the positions of the openings 122 correspond to several bonding pads 102 positioned on the wafer 100. Afterwards, referring to FIG. 3, the photo-resist layer is used as a mask in copper electroplating treatment, so that the educts of copper in the electroplating solution can be adhered onto a portion of the surface using the under bump metallurgy 110 as an electroplating-seed layer, forming a bump structure similar to the copper pillar 112. Next, referring to FIG. 4, the same photo-resist layer 120 is used as the mask in the solder electroplating treatment to form a mushroom-like solder layer 114 on the surface of the copper pillar 112, while the solder layer 114, which can be made of materials such as tin-lead alloy with a low melting point for instance, can therefore be reflown to be a spherical bump via which every chip (not illustrated in the diagram) of the wafer 100 is electrically connected to an external circuit board (not illustrated in the diagram).

At last, referring to FIG. 5, the photo-resist layer 120 is removed, and the portion of the under bump metallurgy 110 not covered by the copper pillar 112 is etched except the portion of the under bump metallurgy 110a disposed at the bottom of the copper pillar 112. Afterwards, the solder layer 114 is reflown, so that the solder layer 114 is melted as a spherical solder bump 114a.

It is noteworthy that since the copper pillar 112 and the solder layer 114 disposed thereon are formed in the same opening 122 of the photo-resist layer 120, the depth of the opening 122 of the photo-resist layer 120 is higher than the height of the copper pillar 112, causing difficulties in exposure and development. Furthermore, the solder layer 114, after filling the opening 122 of the photo-resist layer 120, will be projected from the photo-resist layer 120, so that the two adjacent solder layers 114 are easily electrically connected to each other, causing short-circuit and affecting the reliability of subsequent packages. Besides, the spherical solder bump 114a being adhered to a lateral edge of the copper pillar precipitates the loss of copper ions.

### SUMMARY OF THE INVENTION

It is therefore an object of the invention to provide a bumping process and a structure thereof applicable to a wafer to enhance the quality of the copper pillar and the solder layer in the bumping process and to effectively mitigate the loss of copper ions arising when the solder layer is adhered onto the lateral edge of the copper pillar.

The invention provides a bumping process. The bumping process comprises the steps of: firstly, providing a wafer, wherein the wafer has several chips each has at least a bonding pad positioned on an active surface of the wafer; then, forming a first photo-resist layer on a active surface of the wafer and forming at least a first opening on the first photo-resist layer; next, forming a first copper pillar in the first opening; next, forming a second photo-resist layer on the first photo-resist layer, forming at least a second opening on the second photo-resist layer, and controlling the second opening to be smaller than the first opening for a portion of the surface of the first copper pillar to be exposed in the second opening; then, forming a second copper pillar in the second opening; afterwards, forming a solder layer on the second copper pillar; finally, removing the first and second photo-resist layers.

The first photo-resist layer can be formed by, for example, coating a photosensitive material and forming a first opening using exposure and development. Besides, the second photo-resist layer can be formed by, for example, coating a photosensitive material and forming a second opening using exposure and development.

After the formation of the wafer, the process further comprises forming an RDL and/or an under bump metallurgy on an active surface of the chip with a portion of the surface of the under bump metallurgy being exposed in the first opening. The method of forming an RDL comprises sputtering, evaporating or electroplating. Besides, in the step of forming the first copper pillar, the under bump metallurgy is used as an electroplating-seed layer and dipped in an electroplating solution for the educts of copper to be adhered onto the under bump metallurgy in the first opening. Besides, in the step of forming the second copper pillar, the under bump metallurgy is used as an electroplating-seed layer and dipped in an electroplating solution for the educts of copper to be adhered onto the first copper pillar and its surrounding first photo-resist layer which are disposed in the second opening.

The invention provides a bump structure applicable to a chip. The chip has at least a bonding pad positioned on an active surface of the chip. The bump structure comprises a first copper pillar, a second copper pillar and a solder. The first copper pillar has a first end and a second end, and the first end connects the bonding pad. Besides, the second copper pillar is disposed at the second end, and the cross-section of the second copper pillar is smaller than the cross-section of the first copper pillar. Besides, the solder is disposed on the second copper pillar.

The invention adopts the first and the second photo-resist layers whose openings have different sizes to respectively form the first copper pillar and the second copper pillar in the first opening and the second opening. Besides, a solder layer can be disposed on the copper pillar of the protruded column. After reflowing treatment, the solder layer can be adhered onto a lateral edge of the second copper pillar without being adhered onto the first copper pillar, effective mitigating the loss of copper ions arising when the solder layer is adhered onto the lateral edge of the copper pillar.

Other objects, features, and advantages of the invention will become apparent from the following detailed description of the preferred but non-limiting embodiments. The following description is made with reference to the accompanying drawings.

### BRIEF DESCRIPTION OF THE DRAWINGS

FIG. 1˜FIG. 5 (Prior Art) respectively are a flowchart of a bumping process of a conventional wafer; and

FIG. 6˜FIG. 14 respectively are a flowchart of a bumping process according to a preferred embodiment of the invention.

### DETAILED DESCRIPTION OF THE INVENTION

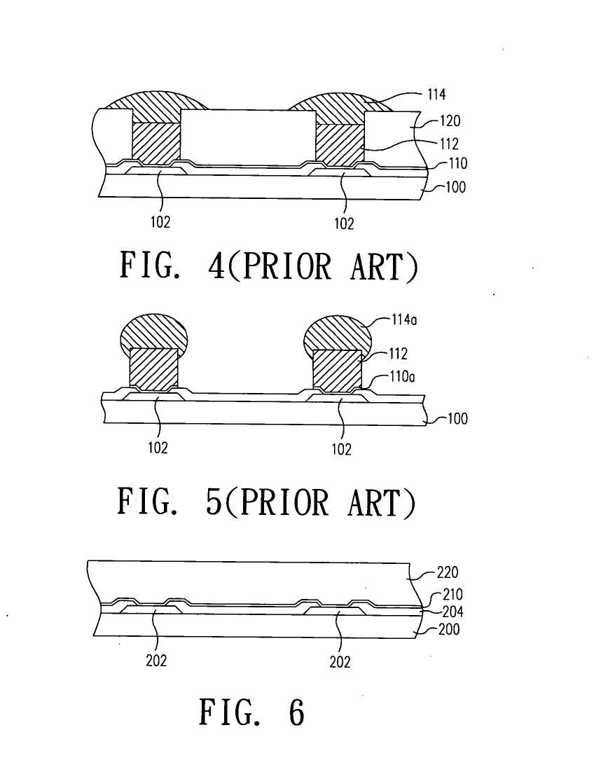

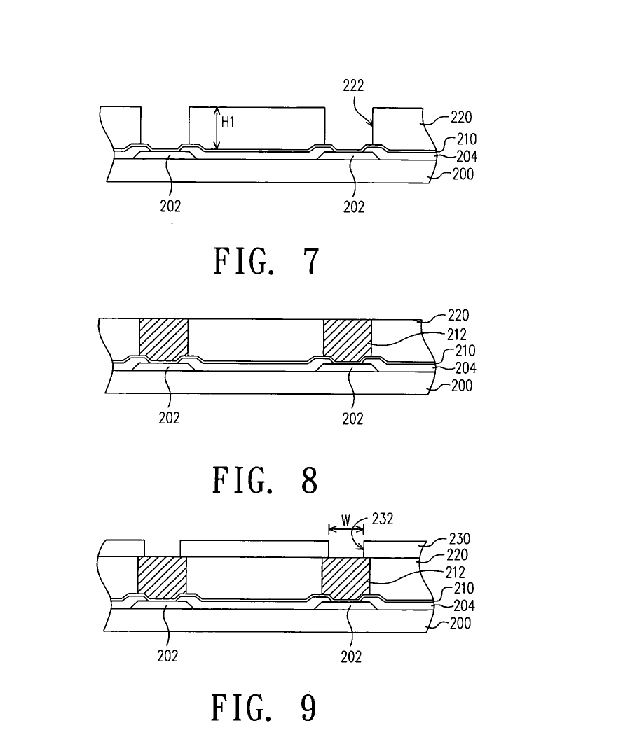

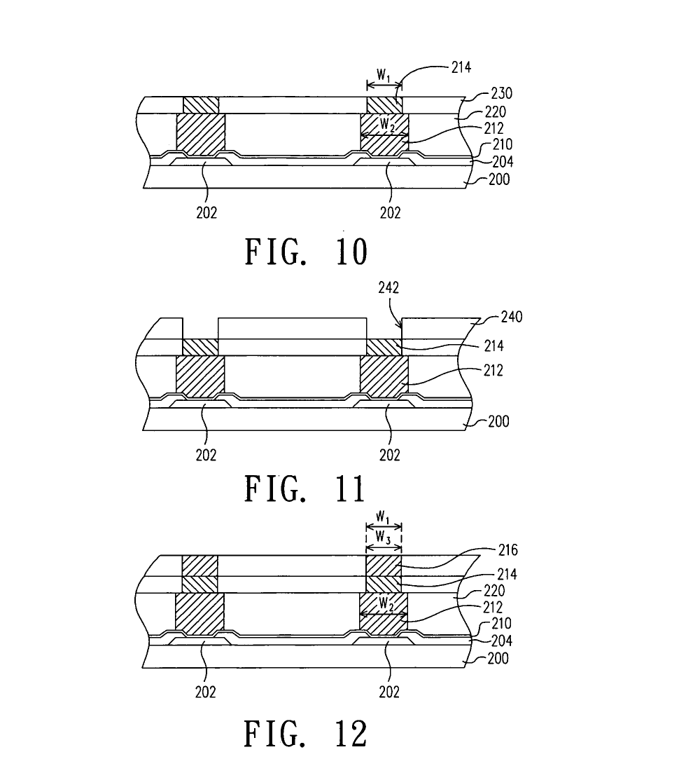

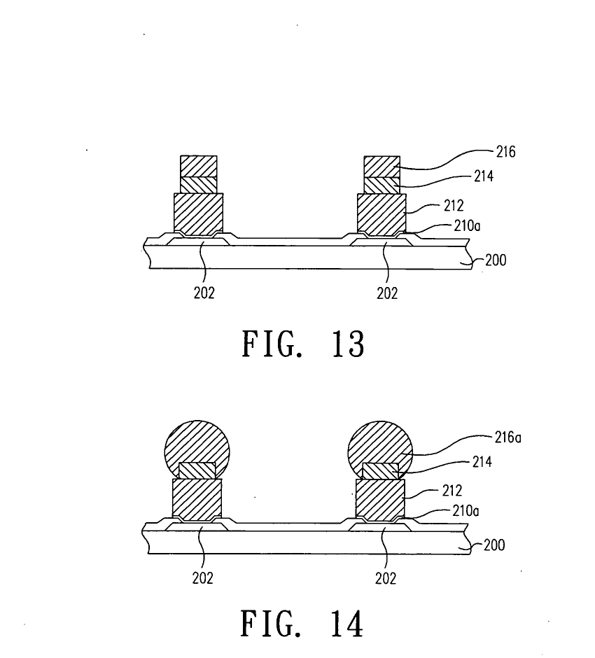

Referring to FIG. 6˜FIG. 14, flowcharts of a bumping process according to a preferred embodiment of the invention are shown. At first, referring to FIG. 6, a wafer 200 is provided, wherein the wafer 200 has several chips (not illustrated in the diagram), and the active surface of every chip has several bonding pads 202 which are exposed in the opening of the passivation layer. Next, an under bump metallurgy (UBM) 210 is formed on the surface of the wafer 200. The under bump metallurgy 210 is a multiple-layered metal layer formed by metals such as copper, nickel, vanadium, and chromium. The under bump metallurgy 210 can be formed on the surface of the wafer 200 using sputtering, evaporating or electroplating for instance, serving as a seed layer for the copper pillar and the solder layer in subsequent electroplating treatment. Besides, the active surface of the wafer 200, in response to the chip structure positioned at different contacting positions, can re-manufacture a re-distribution layer (RDL) (not illustrated in the diagram) or further form the above under bump metallurgy 210 on the RDL to proceed with the subsequent electroplating manufacturing process.

Next, a photosensitive material is coated on the under bump metallurgy 210 to form a first photo-resist layer 220.

Next, referring to FIG. 7, several first openings 222 are formed in the first photo-resist layer 220 using the imaging technology of exposure and development. The first openings 222 respectively expose the under bump metallurgy 210 disposed in the bottom thereof. Next, referring to FIG. 8, the under bump metallurgy 210 is used as an electroplating-seed layer in copper electroplating treatment to form a first copper pillar 212 of appropriate height in the first opening 222. By controlling parameters such as concentration of copper ions in electroplating solution, current time/ampere and so forth, the height of the copper pillar 212 enables the educts of copper to be adhered onto the under bump metallurgy 210 and filled with the first opening 222. As shown in FIG. 7, FIG. 8, since the depth H1 of the opening of the first photo-resist layer 220 is approximately equal to a predetermined height of the first copper pillar 212, the exposure and development would have better quality producing higher resolution and accuracy.

Next, referring to FIG. 9, a second photo-resist layer 230 is formed by coating a photosensitive material. The technology of the invention differs with conventional technology in that the second photo-resist layer 230 with a smaller size W of opening is formed on the first photo-resist layer 220. The second opening 232 of the second photo-resist layer 230 is formed on a portion of the surface of the first copper pillar 214 using the same imaging technology of exposure and development. That is, the size W of the second opening 232 is smaller than the size of the first opening 222 disposed underneath.

Next, referring to FIG. 10, a second copper electroplating treatment is applied to the first copper pillar 212, so that a second copper pillar 214 is formed on the surface of the first copper pillar 212. The second copper pillar 214 is a cylinder or a cuboid for instance, the cross-section W1 of the second copper pillar 214 is smaller than the cross-section W2 of the first copper pillar 212, and the two pillars look like a protruded column. In terms of structure, one end of the first copper pillar 212 is connected to the second copper pillar 214, the cross-section W1 of the second copper pillar 214 is smaller than the cross-section W2 of the first copper pillar 212, and area of the cross-section of the second copper pillar 214 is smaller than the area of the cross-section of the first copper pillar 212 approximately by 80%.

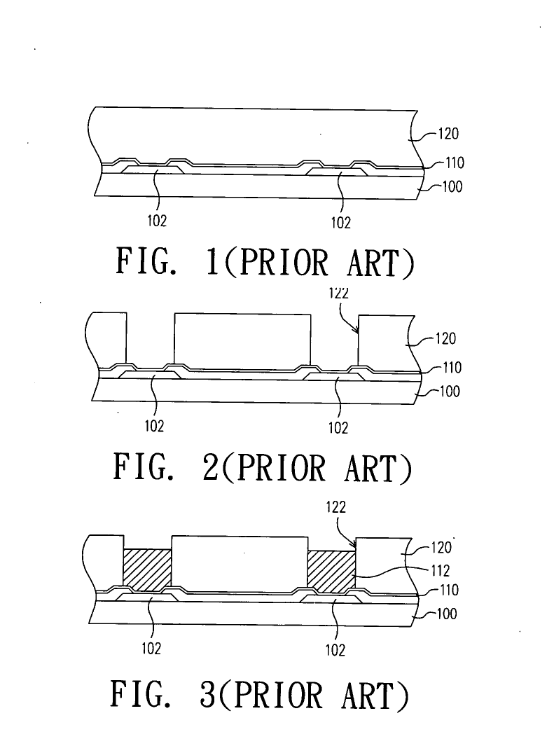

Next, referring to FIG. 11, FIG. 12, a solder layer 216 is formed on the second copper pillar 214 by electroplating or printing. Take the electroplating treatment for example. The electroplating treatment can further comprises forming a third photo-resist layer 240 on the second photo-resist layer 230 and forming several the third opening 242 on the third photo-resist layer 240 using the imaging technology of exposure and development beforehand, and then electroplating a solder 216 in the third opening 242 to form the solder layer 216. The solder layer 216 can be made of materials such as tin-lead alloy with a low melting point or other metals. By controlling parameters such as concentration of metal ions in the electroplating solution, the height of the solder layer 216 enables the metal educts to be adhered onto the second copper pillar 214 and filled with the third opening 242, and enables a bump structure of FIG. 1 to be formed on every bonding pad 202 of the chip. The cross-section W3 of the solder layer 216 can be larger than or equal to the cross-section W1 of the second copper pillar 214, so that the occurrence of short-circuiting between two adjacent solder layers 216 can be reduced accordingly

Next, referring to FIG. 13, the first, the second and the third photo-resist layers 220, 230, and 240 are removed, and the portion of the under bump metallurgy 210 not covered by the first copper pillar 212 is etched except the under bump metallurgy 210a disposed at the bottom of the first copper pillar 212. Then, the solder layer 216 of FIG. 13 is reflown to form a spherical or semi-spherical solder bump 216a as shown in FIG. 14. In the present embodiment, the solder layer 216 can further be adhered onto a lateral edge of the second copper pillar 214 without being adhered onto the surface of the first copper pillar 212. So, the first height of the copper pillar 212 would not be affected even when the loss of copper ions occurs to the second copper pillar 214. After the bumping process of electroplating the first and the second copper pillars 212 and 214 and the solder layer 216 on the surface of the wafer 200 is completed, the wafer 200 can be divided into several independent chips (not illustrated in the diagram), and every chip can be electrically connected to an external electronic device such as a circuit board for instance via the above bump for signals to be transmitted.

It can be seen from the above disclosure that the bumping process of the invention uses multiple manufacturing processes of photoresist-coating, exposure and development to form the first and the second openings with different opening sizes on the first and the second photo-resist layers. Besides, a solder layer can be disposed on the copper pillar of the protruded column. After reflowing treatment, the solder layer is not easy to be adhered onto the lateral edge of the first copper pillar, effective mitigating the loss of copper ions arising when the solder layer is adhered onto the lateral edge of the copper pillar. Besides, the third opening larger than equal to the second opening, so that the height of the third photo-resist layer is reduced due to the use of a third opening having a larger opening so as to enhance the imaging effect. Besides, two adjacent solder layers are less likely to be short-circuited, thus enhancing the reliability of package.

While the invention has been described by way of example and in terms of a preferred embodiment, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A bumping process comprising the steps of:
providing a wafer, wherein the wafer has a plurality of chips, and each of the chips having at least a bonding pad positioned on an active surface of the wafer;
forming a first photo-resist layer on an active surface of the wafer and forming at least a first opening in the first photo-resist layer;
forming a first copper pillar in the first opening;
forming a second photo-resist layer on the first photo-resist layer, forming at least a second opening in the second photo-resist layer, and controlling the second opening to be smaller than the first opening for a portion of the surface of the first copper pillar to be exposed in the second opening;
forming a second copper pillar in the second opening;
forming a solder layer on the second copper pillar; and
removing the first and the second photo-resist layers.

2. The bumping process according to claim 1, wherein the formation of the first photo-resist layer comprises coating a photosensitive material and forming a first opening using exposure and development.

3. The bumping process according to claim 1, wherein the step of forming the second photo-resist layer comprises coating a photosensitive material and forming a second opening using exposure and development.

4. The bumping process according to claim 1, wherein after the step of providing the wafer, the process further comprises forming a re-distribution layer (RDL) on an active surface of the chip.

5. The bumping process according to claim 4, wherein after the step of forming the RDL, the process further comprises forming an under bump metallurgy (UBM) on the RDL with a portion of the surface of the under bump metallurgy being exposed in the first opening.

6. The bumping process according to claim 1, wherein after the step of providing the wafer, the process further comprises forming an under bump metallurgy (UBM) on an active surface of the wafer with a portion of the surface of the under bump metallurgy being exposed in the first opening.

7. The bumping process according to claim 1, wherein the step of forming the first copper pillar and the second copper pillar comprises using electroplating.

8. The bumping process according to claim 1, wherein the step of forming the solder layer comprising using electroplating to adhere the educts of tin and lead onto the second copper pillar.

9. The bumping process according to claim 1, wherein before the step of forming the solder layer, the process further comprises:
forming a third photo-resist layer on the second photo-resist layer;
forming at least a third opening on the third photo-resist layer to expose a portion of the surface of the second copper pillar; and
electroplating the solder layer in the third opening.

10. The bumping process according to claim 9, wherein the step of forming the third photo-resist layer comprises coating a photosensitive material and forming the third opening using exposure and development.

11. The bumping process according to claim 9, wherein after the step of forming the solder layer, the process further comprises removing the third photo-resist layer.

12. The bumping process according to claim 1, wherein the step of forming the solder layer comprises screen-printing a solder.

13. The bumping process according to claim 5, wherein after the step of removing the first and the second photo-resist layers, the process further comprises removing a portion of the under bump metallurgy not covered by the first copper pillar.

14. The bumping process according to claim 6, wherein after the step of removing the first and the second photo-resist layers, the process further comprises removing a portion of the under bump metallurgy not covered by the first copper pillar.

15. The bumping process according to claim 1, wherein after the step of removing the first and the second photo-resist layers, the process further comprises reflowing the solder layer.

16. A bump structure applicable to a chip, wherein the chip has at least a bonding pad positioned on an active surface of the chip, the bump structure comprises:
a first copper pillar having a first end and a second end, wherein the first end connects the bonding pad;
a second copper pillar disposed on the second end, wherein the cross-section of the second copper pillar is smaller than the cross-section of the first copper pillar; and
a solder disposed on the second copper pillar.

17. The bump structure according to claim 16, wherein the area of cross-section of the second copper pillar is smaller than the area of the cross-section of the first copper pillar by 80%.

18. The bump structure according to claim 16, wherein the solder is further adhered onto a lateral edge of the second copper pillar.

19. The bump structure according to claim 16, further comprising an under bump metallurgy electrically connected to a region between the bonding pad and the first end of the first copper pillar.

20. The bump structure according to claim 16, further comprising an RDL electrically connected to a region between the bonding pad and the first end of the first copper pillar.
